(19) United States
(12) Patent Application Publication
(10) Pub. No.: US 2026/0063673 A1
(43) Pub. Date: Mar. 5, 2026

(54) ASYMMETRIC ACQUISITIONS AND DISJOINT TIME TRIGGER IN A TEST AND MEASUREMENT INSTRUMENT

(71) Applicant: Tektronix, Inc., Beaverton, OR (US)

(72) Inventor: Ronald Allan Brown, Portland, OR (US)

(21) Appl. No.: 19/299,708

(22) Filed: Aug. 14, 2025

Related U.S. Application Data
(60) Provisional application No. 63/688,259, filed on Aug. 28, 2024.

(51) Int. Cl. G01R 13/02

(52) U.S. Cl. CPC G01R 13/0218

(57) ABSTRACT

A test and measurement instrument includes two or more channels to allow the test and measurement instrument to connect to a device under test (DUT), each channel comprising an analog-to-digital converter (ADC) and one or more trigger engines, each trigger engine to determine one or more trigger conditions, a display to allow the test and measurement instrument to display data from the ADC, a user interface, and one or more processors configured to execute code to cause the one or more processors to acquire data from the two or more channels at a different time than others of the two or more channels in response to one or more trigger conditions. A test and measurement instrument similar to the above except it has at least one channel that has an auxiliary input and a threshold detector instead of an ADC in addition to one or more channels having ADCs.

### CROSS-REFERENCE TO RELATED APPLICATIONS

This disclosure is a non-provisional of and claims benefit from U.S. Provisional Application No. 63/688,259, titled “ASYMMETRIC ACQUISITIONS AND DISJOINTED TIME TRIGGER IN A TEST AND MEASUREMENT INSTRUMENT,” filed on Aug. 28, 2024, the disclosure of which is incorporated herein by reference in its entirety.

### TECHNICAL FIELD

This disclosure relates to test and measurement instruments, and more particularly to acquisition and triggering techniques in a test and measurement instrument, such as an oscilloscope.

### BACKGROUND

In a traditional oscilloscope, all input channels are sampled at the same rate in a time-synchronous manner based on a trigger condition. While the trigger condition might occur on a single channel or span multiple channels, all channels are acquired at the same time and sample rate for a particular coherent data set. Many existing oscilloscopes have one trigger engine responsible for determining the slice of time to acquire.

Test and measurement instruments such as oscilloscopes do not currently have the capability to allow a user to configure the instrument to acquire a channel of interest using more resources, while sampling other channels at a lower sample or acquisition rate. Current oscilloscopes may use an auxiliary input as a trigger or part of a trigger, but do not display the waveform. The user may manually move the auxiliary input to an analog channel to view the waveform but has no way to accomplish that outside of manual intervention.

### BRIEF DESCRIPTION OF THE DRAWINGS

FIG. 1 shows an embodiment of a test and measurement device having asymmetric acquisitions.

FIG. 2 shows an embodiment of channels in a test and measurement device.

FIG. 3 shows an embodiment of a process of acquiring and examining waveforms using disjoint time triggers.

FIG. 4 shows a rotatable 3D rendering of asymmetric acquisitions.

### DETAILED DESCRIPTION

The embodiments described herein include a test and measurement instrument and a method of acquiring data from different channels independent from other channels in a configurable manner. The channels may acquire data independently by acquiring data at different times, different sample rates, in response to different trigger conditions, or any combination thereof. The independently acquired data may then be combined to make up one coherent data set across times, rates, and events.

As an example, one process may acquire individual channels, or a subset of all channels, based on a trigger condition, which includes a time reference, observed on that channel or subset of channels. For example, the channel 1 acquisition could be based on a rising edge on channel 1, and the channel 2 acquisition could be based on a rising edge on channel 2. The same could be done for any trigger type, such as a rising edge, a falling edge, a pulse width, a specific bit pattern in a serial transmission, etc. The discussion here refers to the result as a coherent acquisition, where part of the acquisition is the measured time alignment between the individual channel captures. In this example, a traditional aligned acquisition would essentially have a delta time of zero for all channels.

This discussion refers to the data acquisitions as “asymmetric acquisitions” in that acquisitions occur with some asymmetry, such as different trigger times, different trigger types, different sample rates, or combination thereof. The term “disjoint time triggers” as used here means those acquisitions where the trigger conditions occur at a different time with respect to each channel. Triggers may occur at the same time, even if they are different triggers on different channels, but the channels trigger independently.

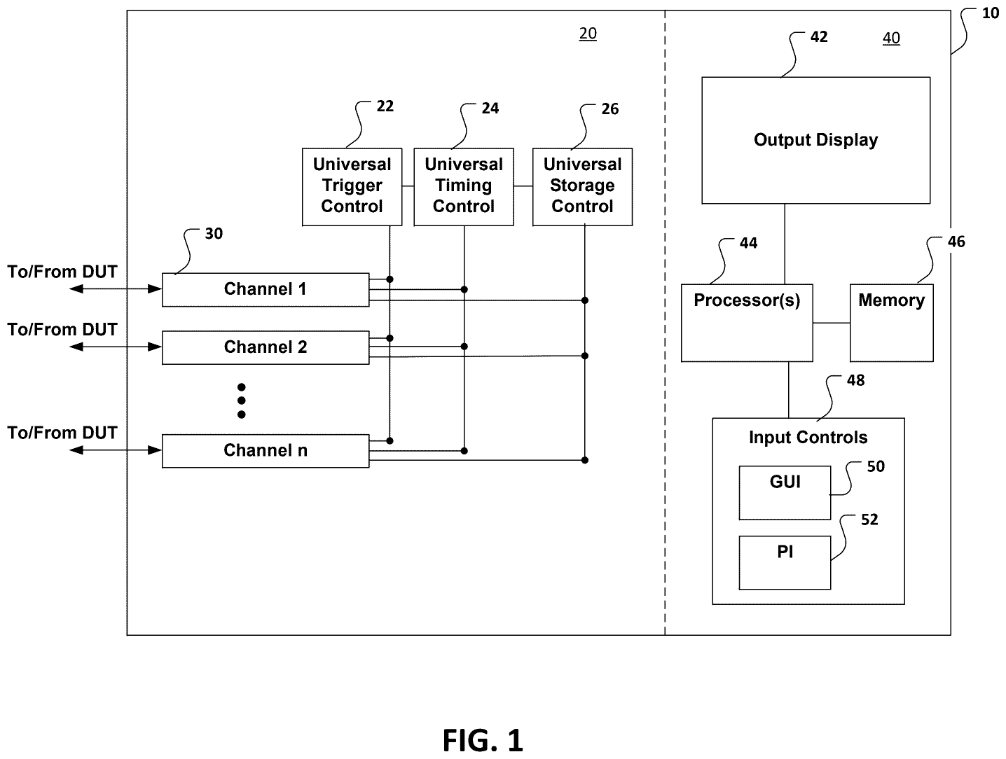

FIG. 1 is a block diagram of a test and measurement instrument 10 having multiple channels. The test and measurement instrument 10 includes a portion that interacts with devices under test (DUTs), referred to here as the input/output portion 20, as well as a display and control portion 40. The input/output portion 40 of the instrument 10 includes multiple channels such as 30, labeled Channel 1, Channel 2, through Channel n. The instrument may include any number of channels.

As described in more detail below, instrument 10 may include a universal timing control 24, a universal trigger control 22, and a universal storage control 26. In FIG. 1, these components appear to reside within the input/output portion 20 of the instrument 10, but they could be physically located anywhere in the instrument 10.

The control portion 40 of the instrument 10 includes a set of input controls 48, through which a user can control the instrument. The input controls 48 may include a Graphical User Interface (GUI) 50 or a programmatic interface (PI) 52. Other input controls 48 may include various knobs and switches on or remote from the instrument 100 as is conventionally known.

One or more main, or central, processors 44 may be configured to execute instructions from a memory 46 and may perform any methods and/or associated steps indicated by such instructions, such as receiving and storing the acquired signals from the input/output portion 20 or performing any test and measurement functions of the instrument 10. The instrument may store acquired signals as waveforms in memory 46, in one or more acquisition memories associated with the channels, or in other various memories that may be located throughout the instrument 10.

The one or more processors 44 may control an output display 42 to display waveforms, measurements, and other data to the user. The output display 42 may comprise, for example, an LCD or any other display monitor. The display may also be part of the input controls if the display comprises a touch screen.

While FIG. 1 shows the components of the test and measurement instrument 10 as integrated within one test and measurement instrument 10, a person of ordinary skill in the art will appreciate that any of these components can reside external to the test and measurement instrument 10 and can be coupled to the test and measurement instrument 10 in any conventional manner, such as wired and/or wireless communication media and/or mechanisms. In some embodiments a remote computer may connect to instrument 10 to operate the instrument.

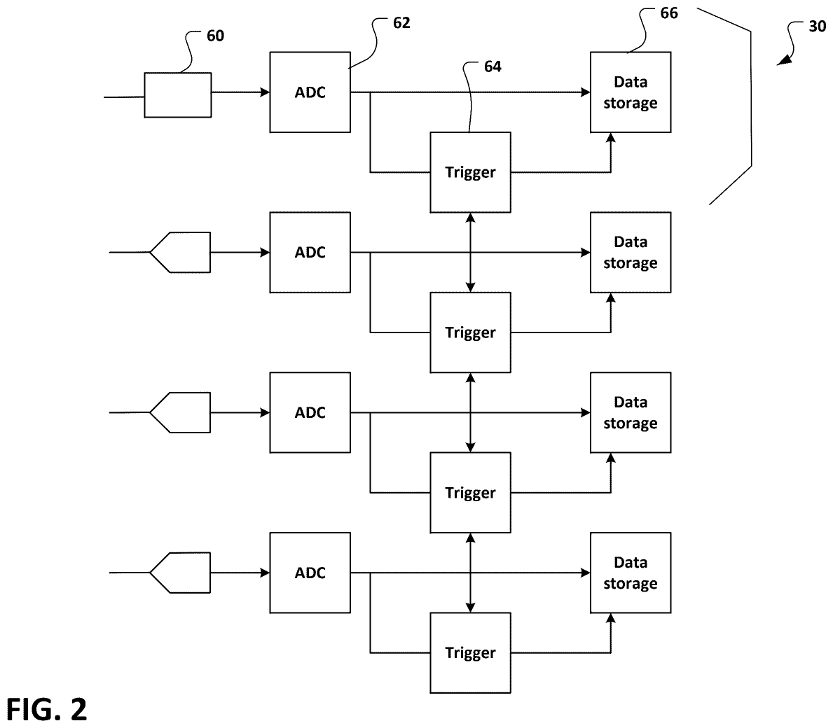

Further, while the universal trigger control 22, the universal timing control, 24 and the universal storage control 26 may comprise a shared component among the channels, the individual channels may include a trigger module or engine. This trigger engine in each channel may provide the capability for each channel to trigger and acquire independent of the other channels. FIG. 2 shows a more detailed representation of an embodiment of the channels such as 30 from FIG. 1.

FIG. 2 shows a four-channel configuration with the understanding that FIG. 2 shows an example, and the instrument may have more or fewer channels. The instrument will have one or more channels that can acquire data from DUT independent of other channels. The data enters the channel from the DUT and may undergo signal conditioning such as amplification at amplifier/receiver 60. The analog-to-digital converter (ADC) 62 then samples the signal and converts it into digital data. When the trigger engine 64 detects a trigger event in the data stream from the ADC 62, it then directs the data storage 66 to store the data. One should note that the channels may share these components, such as the amplifier, ADC, and storage.

The trigger engine may comprise a processing element of some type, such as a field-programmable gate array (FPGA), an application specific integrated circuit (ASIC), or other processing element that may receive programming or otherwise be controlled by one or more central processors 44 of instrument 10 from FIG. 1. The one or more processors 44 of the instrument 10 may include the processing elements that reside in the trigger engines. The one or more central processors may also control the trigger engines without the trigger engines having any processing elements. However, implemented, the trigger engines receive signals to control acquisitions independent from acquisitions made on other channels.

In some embodiments each channel includes a full copy of the trigger capability on each acquisition circuit, meaning each channel.

The test and measurement instrument having independent channels means that the channels may acquire data independently in many ways. to cause the one or more processors to acquire the data in response to a different trigger condition on at least one of the two or more channels than for others of the two or more channels.

In one embodiment, the channels may respond to the same trigger condition occurring on each of the two or more channels at different times. In this embodiment, the instrument may trigger using a single trigger, but the different trigger engines start the acquisition at different times. In another embodiment the channels may acquire data in response to a different trigger condition on at least one of the two or more channels than for others of the two or more channels. This corresponds to the example above of the rising edges that cause the acquisition on a rising edge on channel 1 and a rising edge on channel 2.

In one embodiment, the instrument could use this capability to analyze transmission effects on a signal. The conditions could be RF energy in a specific band on each channel exceeding a threshold. For example, a wireless communications signal might be transmitted and received, where source and destination signals are both sampled by an oscilloscope. The characteristics of the path, such as frequency response, path delay, multi-path interference, etc. might be more easily visualized with the source and destination signals overlaid or stacked at a reference point, such as the start of the burst. Wireless environments are by nature dynamic, and sometimes highly dynamic when the transmitter or receiver are moving. Automatically aligning the source and receiver data would let the user concentrate on the signal effects.

This would allow users to analyze received signals as a function of transmission time from a transmitter reference. For example, the change in characteristics of received waveforms of a radar signal could be visualized by rendering the sampled waveforms as a function of the transmission time, which might generally correspond to the distance to the target.

In wired communication, the signal in question is effectively constrained to a wave guide. Similarly, transmission effects of a wire or circuit board trace could be analyzed as a function of time delay, which might correspond to the wire or trace length.

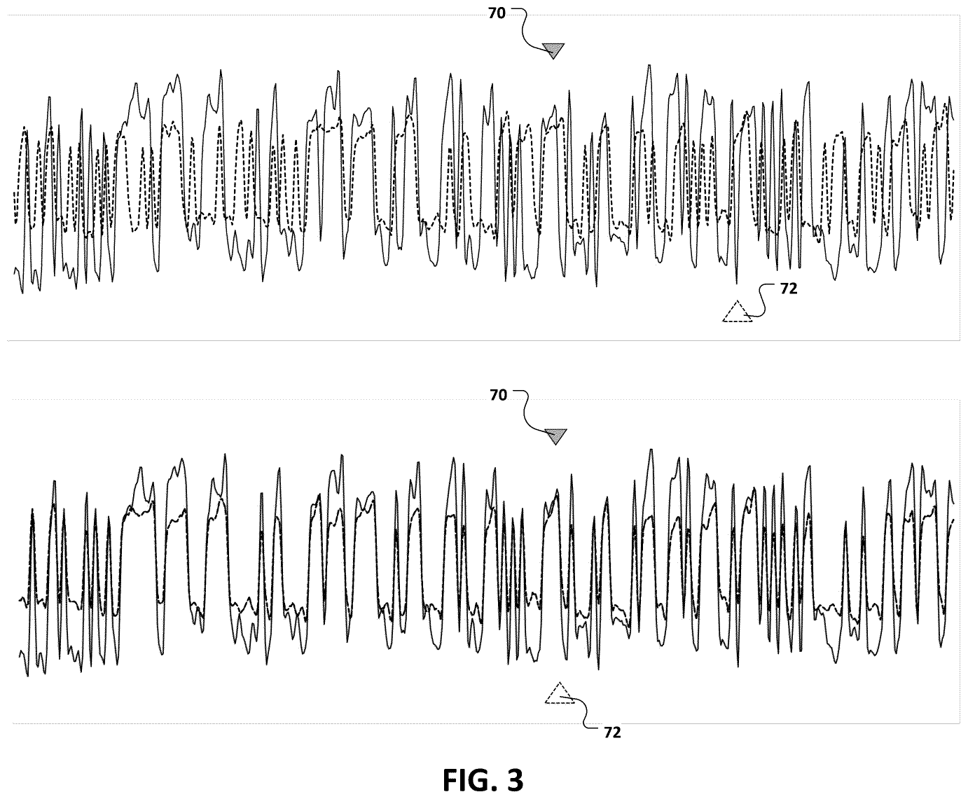

In embodiments wherein each channel has full triggering capability, software, and the individual processors, such as FPGA images on existing hardware, can be modified to independently trigger on a condition, such as an edge, on each channel, and then collect and align them for display. FIG. 3 shows an example of such acquisitions.

In FIG. 3, the solid lines comprise a signal acquired on one channel from near the source of the transmission, and the dashed line comprises a signal acquired on a different channel near the receiver. These signals are in a wire. The top graph shows how the results of triggering would appear without disjoint time triggering. The trigger is configured for a specific pattern of data. Due to the transmission time of the signal, the captured waveforms are not aligned on the display, making comparison difficult. A reference point in the signal pattern is identified, for the source signal by the triangle pointer 70, and in the receiver waveform by the triangle pointer 72.

In the bottom graph, the two channels separately trigger on the same pattern in the data, without a need to know the transmission time. The two triangle pointers 70 and 72 are now aligned as trigger references. This allows the user to probe additional points and always get a clear comparison of the two or more waveforms. The offset is determined automatically, changing the emphasis from the delay in the probed signal to the change in the shape of the probed signal, which generally results from transmission line loss.

The embodiments herein change an assumption inherent in the UI of conventional test and measurement instruments, that the displayed waveforms were captured at exactly the same time and in the same way. The point of the “asymmetric acquisition” or “disjoint time acquisition” mode, is that waveforms are deliberately not captured at the same time.

Another benefit to triggering at different times allows for capturing a change (delta) between those times as an axis on the graph. The time difference of disjoint time acquisitions is itself a measurable and plottable value. For example, as a wireless receiver approaches a transmitter, the transmission delay changes as well as the received waveform characteristics. An oscilloscope could render this in a 3D projection showing the received waveform as a function of transmission time, or effectively distance.

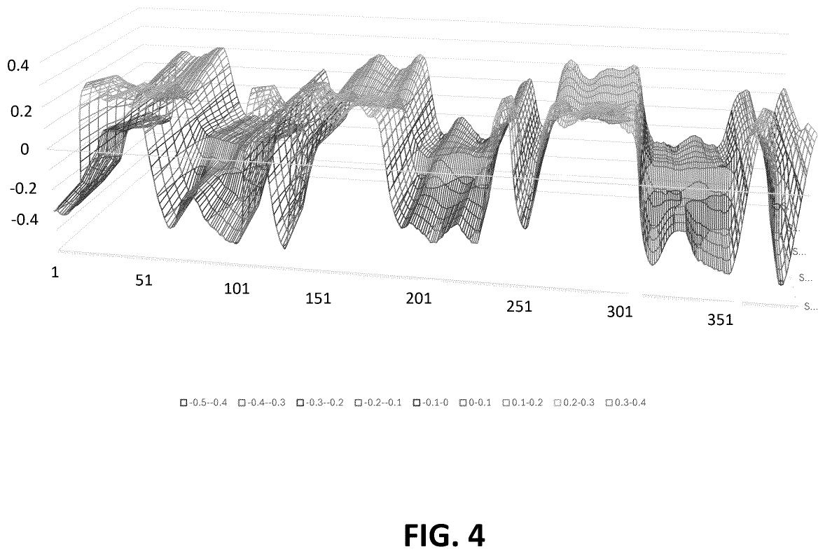

FIG. 4 shows an example of this type of projection. The two axes are amplitude on the vertical axis, and time on the horizontal axis. The third axis could be transmission time. In this figure, the third axis going in and out of the page visualizes the change in the signal as a function of transmission time, given a probe on the transmitter and a probe on the receiver. This image could constantly update as the two DUTs operate and the conditions around the DUT change.

This graph may be rendered on the user interface display of a test and measurement instrument such that the user can manipulate the view angle, for example, to better understand the distortion of a signal as a function of transmission distance or time. An instrument could also make use of color or gray scale to identify the different transmission time acquisitions, in either a two-dimensional or three-dimensional projection, such as the one shown in FIG. 4.

One could also use this to capture distortion along a wire. The ability to use disjoint time triggers makes the testing far easier to set up. A user could set up the oscilloscope once to trigger on source and destination at separate times on different channels, and then easily step through different DUTs at different wire lengths without the need to reconfigure the oscilloscope for the different flight times. In that case the flight time is not as interesting, but it does provide ease of use factors where the user does not care about the time alignment of the channels.

In some embodiments, useful information could be revealed by cross-correlation of the two signals over many acquisitions. Potentially an advanced filter, including a learning filter, could be used, and the oscilloscope could trigger on anomalous differences or correlations, where the term “difference” indicates a negative correlation, and “correlation” implies a positive correlation, where the difference or correlation exceeds a threshold from other differences or correlations. The advantage of independent triggering is that it could be used to remove the time difference between the sampling points as a factor that impedes the analysis, particularly for cases where that time difference is changing.

In some hardware designs, high-performance processing like Fast Frame or Fast Acq (acquisition) requires intensive resource use during acquisition. An oscilloscope or instrument could explicitly let a user configure the instrument to acquire a channel or channels of interest with maximum resource “intensity,” while sampling other channels at a lower sample rate or acquisition rate. This would permit a higher-fidelity result, such as a higher “live time” for a channel of interest, while still monitoring other signals, which might be monitored just to provide a frame of reference.

A common current oscilloscope configuration uses an “auxiliary,” or “aux,” input as the trigger or part of the trigger but does not display the waveform. In some use cases, a user will manually move a signal from the aux input to one of the analog inputs to allow the user to see the aux signal. The instrument could render the state of an “aux trig” signal, which has only two states and might not be sampled at the same sample rate as other channels, as another asymmetric acquisition, according to some embodiments of the disclosure.

In summary, embodiments of the disclosure improve two general areas of test and measurement instrument operation. First, the embodiments make the most of finite hardware resources, to maximize the useful information that is collected and presented to a user. Second, the embodiments increase user efficiency by helping a user to understand a complex set of data by aligning events that happen at different and potentially unpredictable times for a quicker route to understanding the captured information.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, comprising: two or more channels to allow the test and measurement instrument to connect to a device under test (DUT), each channel comprising an analog-to-digital converter (ADC) and one or more trigger engines, each trigger engine to determine one or more trigger conditions; a display to allow the test and measurement instrument to display data from the ADC; a user interface; and one or more processors configured to execute code to cause the one or more processors to acquire data from the two or more channels at a different time than others of the two or more channels in response to one or more trigger conditions.

Example 2 is the test and measurement instrument of Example 1, wherein the one or more processors comprise a central processor and a processor for each of the two or more channels.

Example 3 is the test and measurement instrument of Example 2, wherein the one or more trigger engines comprise one trigger engine for each channel, each trigger engine having one of the one or more processors.

Example 4 is the test and measurement instrument of any of Examples 1 through 3, wherein the one or more processors comprise one or more central processors and the one or more trigger engines are controlled by the one or more central processors.

Example 5 is the test and measurement instrument of any of Examples 1 through 4, wherein the ADC is shared between the two or more channels.

Example 6 is the test and measurement instrument of any of Examples 1 through 5, wherein the code that causes the one or more processors to acquire the data from the two or more channels comprises code to cause the one or more processors to acquire the data in response to a different trigger condition on at least one of the two or more channels than for others of the two or more channels.

Example 7 is the test and measurement instrument of any of Examples 1 through 6, wherein the code that causes the one or more processors to acquire the data comprises code that causes the one or more processors to acquire the data based upon a same trigger condition occurring on each of the two or more channels at different times.

Example 8 is the test and measurement instrument of any of Examples 1 through 7, wherein the code that causes the one or more processors to acquire the data comprises code to cause the one or more processors to acquire the data on each of the two or more channels in response to independent trigger conditions for each of the two or more channels, and the one or more processors are further configured to: align the data for each of the two or more channels in time to produce aligned data; and display the aligned data for all of the two or more channels on the display.

Example 9 is the test and measurement instrument of any of Examples 1 through 8, wherein the one or more processors are further configured to execute code to: track a time difference between times of data acquisitions on different channels of the two or more channels; and plot the time differences on the display.

Example 10 is the test and measurement instrument of any of Examples 1 through 9, wherein the code that causes the one or more processors to display the time differences causes the one or more processors to display the time differences using a rotatable, three-dimensional graph.

Example 11 is the test and measurement instrument of any of Examples 1 through 10, wherein the one or more processors are further configured to execute code that causes the one or more processors to: detect one of either correlations or differences between two signals on different channels of the two or more channels over a period of time; and identify differences that exceed a threshold difference during the period of time.

Example 12 is a test and measurement instrument, comprising: one or more channels to allow the instrument to connect to a device under test (DUT) comprising an analog-to-digital converter (ADC) and a trigger engine each trigger engine to determine one or more trigger conditions; one or more channels to allow the instrument to connect to a device under test (DUT) comprising an auxiliary input having a threshold detector and a trigger engine each trigger engine to determine one or more trigger conditions; a display to allow the instrument to display data from the ADC; a user interface; and one or more processors configured to execute code to cause the one or more processors to: acquire data from the one or more channels having ADCs; and sample the auxiliary input separate from the one or more channels having ADCs.

Example 13 is a method, comprising: determining one or more trigger conditions; and acquiring data from two or more channels connected to a device under test (DUT) at a different time than others of the two or more channels in response to one or more trigger conditions.

Example 14 is the method of Example 13, wherein acquiring the data comprises acquiring the data in response to a different trigger condition on at least one of the two or more channels than for others of the two or more channels.

Example 15 is the method of either of Examples 13 or 14, wherein acquiring data comprises acquiring the data based upon a same trigger condition occurring on each of the two or more channels at different times.

Example 16 is the method of any of Examples 13 through 15, acquiring the data further comprises: acquiring the data on each of the two or more channels in response to independent trigger conditions for each of the two or more channels; aligning the data for each of the two or more channels based upon the independent trigger conditions for each of the two or more channels to produce aligned data having aligned time differences and aligned channels; and displaying the aligned data for all of the two or more channels on a display on a test and measurement instrument.

Example 17 is the method of Example 16, wherein displaying the aligned time differences comprises displaying the aligned time differences using a three-dimensional graph indicating the aligned time differences on the display by one of a waveform plotted position, shades of gray or color.

Example 18 is the method of any of Examples 13 through 17, further comprising: tracking a time difference between times of data acquisitions on different channels of the two or more channels; and plotting the time differences on a display.

Example 19 is the method of any of Examples 13 through 18, further comprising: detecting differences between two signals on different channels of the two or more channels over a period of time; and identifying differences that exceed a threshold difference during the period of time.

Example 20 is the method of Example 16, further comprising generating another further trigger condition to watch for differences on the aligned channels and displays results when a difference threshold is exceeded.

The previously described versions of the disclosed subject matter have many advantages that were either described or would be apparent to a person of ordinary skill. Even so, these advantages or features are not required in all versions of the disclosed apparatus, systems, or methods.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
two or more channels to allow the test and measurement instrument to connect to a device under test (DUT), each channel comprising an analog-to-digital converter (ADC) and one or more trigger engines, each trigger engine to determine one or more trigger conditions;
a display to allow the test and measurement instrument to display data from the ADC;
a user interface; and
one or more processors configured to execute code to cause the one or more processors to acquire data from the two or more channels at a different time than others of the two or more channels in response to one or more trigger conditions.

2. The test and measurement instrument as claimed in claim 1, wherein the one or more processors comprise a central processor and a processor for each of the two or more channels.

3. The test and measurement instrument as claimed in claim 2, wherein the one or more trigger engines comprise one trigger engine for each channel, each trigger engine having one of the one or more processors.

4. The test and measurement instrument as claimed in claim 1, wherein the one or more processors comprise one or more central processors and the one or more trigger engines are controlled by the one or more central processors.

5. The test and measurement instrument as claimed in claim 1, wherein the ADC is shared between the two or more channels.

6. The test and measurement instrument as claimed in claim 1, wherein the code that causes the one or more processors to acquire the data from the two or more channels comprises code to cause the one or more processors to acquire the data in response to a different trigger condition on at least one of the two or more channels than for others of the two or more channels.

7. The test and measurement instrument as claimed in claim 1, wherein the code that causes the one or more processors to acquire the data comprises code that causes the one or more processors to acquire the data based upon a same trigger condition occurring on each of the two or more channels at different times.

8. The test and measurement instrument as claimed in claim 1, wherein the code that causes the one or more processors to acquire the data comprises code to cause the one or more processors to acquire the data on each of the two or more channels in response to independent trigger conditions for each of the two or more channels, and the one or more processors are further configured to:
align the data for each of the two or more channels in time to produce aligned data; and
display the aligned data for all of the two or more channels on the display.

9. The test and measurement instrument as claimed in claim 1, wherein the one or more processors are further configured to execute code to:
track a time difference between times of data acquisitions on different channels of the two or more channels; and
plot the time differences on the display.

10. The test and measurement instrument as claimed in claim 1, wherein the code that causes the one or more processors to display the time differences causes the one or more processors to display the time differences using a rotatable, three-dimensional graph.

11. The test and measurement instrument as claimed in claim 1, wherein the one or more processors are further configured to execute code that causes the one or more processors to:
detect one of either correlations or differences between two signals on different channels of the two or more channels over a period of time; and
identify differences that exceed a threshold difference during the period of time.

12. A test and measurement instrument, comprising:
one or more channels to allow the instrument to connect to a device under test (DUT) comprising an analog-to-digital converter (ADC) and a trigger engine each trigger engine to determine one or more trigger conditions;
one or more channels to allow the instrument to connect to a device under test (DUT) comprising an auxiliary input having a threshold detector and a trigger engine each trigger engine to determine one or more trigger conditions;
a display to allow the instrument to display data from the ADC;
a user interface; and
one or more processors configured to execute code to cause the one or more processors to:
acquire data from the one or more channels having ADCs; and
sample the auxiliary input separate from the one or more channels having ADCs.

13. A method, comprising:
determining one or more trigger conditions; and
acquiring data from two or more channels connected to a device under test (DUT) at a different time than others of the two or more channels in response to one or more trigger conditions.

14. The method as claimed in claim 13, wherein acquiring the data comprises acquiring the data in response to a different trigger condition on at least one of the two or more channels than for others of the two or more channels.

15. The method as claimed in claim 13, wherein acquiring data comprises acquiring the data based upon a same trigger condition occurring on each of the two or more channels at different times.

16. The method as claimed in claim 13, acquiring the data further comprises:
acquiring the data on each of the two or more channels in response to independent trigger conditions for each of the two or more channels;
aligning the data for each of the two or more channels based upon the independent trigger conditions for each of the two or more channels to produce aligned data having aligned time differences and aligned channels; and
displaying the aligned data for all of the two or more channels on a display on a test and measurement instrument.

17. The method as claimed in claim 16, wherein displaying the aligned time differences comprises displaying the aligned time differences using a three-dimensional graph indicating the aligned time differences on the display by one of a waveform plotted position, shades of gray or color.

18. The method as claimed in claim 13, further comprising:
tracking a time difference between times of data acquisitions on different channels of the two or more channels; and
plotting the time differences on a display.

19. The method as claimed in claim 13, further comprising:
detecting differences between two signals on different channels of the two or more channels over a period of time; and
identifying differences that exceed a threshold difference during the period of time.

20. The method as claimed in claim 16, further comprising generating another further trigger condition to watch for differences on the aligned channels and displays results when a difference threshold is exceeded.
